(19) United States
(12) Patent Application Publication
(10) Pub. No.: US 2023/0120027 A1
(43) Pub. Date: Apr. 20, 2023

(54) METAL ENCLOSURE FOR ELECTRICAL COMPONENTS

(71) Applicant: Hardcraft Industries, Inc., San Jose, CA (US)

(72) Inventor: Brandt Kwiram, Piedmont, CA (US)

(21) Appl. No.: 17/503,505

(22) Filed: Oct. 18, 2021

(51) Int. Cl. H05K 5/04; H05K 5/06; H05K 5/02

(52) U.S. Cl. CPC H05K 5/04; H05K 5/061; H05K 5/0226; H05K 5/0221

(57) ABSTRACT

A metal enclosure for electrical components may include a rear panel and four side panels coupled with adhesive to form a bonded case having a cavity with a front opening. Channels of the four side panels may be joined to form a case channel circumscribing the opening. The case channel may be recessed towards a center of the opening so as to not extend radially beyond an envelope formed by planes of main panes of the four side panels of the one of the two adjoined panels or the one of the two separate panels. A door may be hingedly connected to one of the four side panels and may have one or more latches installed thereon. When the door is closed, a gasket engages a main panel of the door and a front surface of the case channel to seal the metal enclosure.

### FIELD OF THE INVENTION

The present disclosure relates to outdoor enclosures or cabinets suitable for housing electrical components, control systems, and the like.

### BACKGROUND

Electrical power providers, utilities, telephone companies, cable service providers, etc. use outdoor enclosures or cabinets to protect electrical and/or electronic equipment that forms part of their systems or networks and that must be installed outside of buildings. Because of the outdoor installation, these enclosures or cabinets must often provide robust protection for the components in the interior of the enclosure. Such protection may include protection against corrosion, protection against mechanical intrusion, vandalism, earthquakes, protection against electromagnetic interference, etc. Because of the outdoor installation, these enclosures or cabinets must often also provide robust protection from electric and electronic components therein for other equipment and people in the area surrounding the enclosure. Such protection may include protection from electromagnetic emissions, protection against current-carrying parts with dangerous voltages, protective grounding or protective insulation, protection against sparks exiting the enclosure, protection against water and dust intrusion, etc.

Manufacturers produce outdoor enclosures or cabinets from sheet metal, fiberglass, or plastic, depending on the required size and intended application. For certain sizes and applications, outdoor enclosures or cabinets are typically made from sheet metal cut and/or stamped and bent into panels or other parts that are then mechanically joined to one another, for example by spot or linear welding. Welding construction has conventionally been considered the best and/or only solution because of the strict demands on the cabinets, as described above.

Unfortunately, the involved labor and other costs of spot or linear welding can be significant, rendering the produced outdoor enclosures or cabinets too expensive especially in environments where a large fleet of enclosures is to be deployed. The high thermal stresses produced by conventional welding techniques frequently also result in dimensional distortion of the welded parts, which can be highly undesirable.

There is a need in the art for alternatives to extensive welding construction of sheet metal-based outdoor enclosures or cabinets.

### SUMMARY OF THE INVENTION

The present disclosure provides a metal enclosure made from various parts and configured to be assembled by gluing the various parts together using adhesive without the need for significant welding. Although, the disclosed enclosure does not involve any or at least no significant welding, the enclosure provides weather, dust, electric, and electromagnetic protection/shielding. Moreover, given that adhesive bonding of components is significantly less expensive than welding, the enclosure as disclosed herein may be fabricated at a significantly lesser cost than prior art welded enclosures.

The accompanying drawings, which are incorporated in and constitute a part of the specification, illustrate various example systems, methods, and so on, that illustrate various example embodiments of aspects of the invention. It will be appreciated that the illustrated element boundaries (e.g., boxes, groups of boxes, or other shapes) in the figures represent one example of the boundaries. One of ordinary skill in the art will appreciate that one element may be designed as multiple elements or that multiple elements may be designed as one element. An element shown as an internal component of another element may be implemented as an external component and vice versa. Furthermore, elements may not be drawn to scale.

### BRIEF DESCRIPTION OF THE DRAWINGS

FIG. 1 illustrates a perspective view of an exemplary metal enclosure for electrical components.

FIG. 2 illustrates an exploded view of the exemplary metal enclosure for electrical components of FIG. 1.

FIG. 3 illustrates a front view of the exemplary metal enclosure for electrical components of FIG. 1.

FIG. 4 illustrates a top view of the exemplary metal enclosure for electrical components of FIG. 1.

FIG. 5 illustrates a side view of the exemplary metal enclosure for electrical components of FIG. 1.

FIG. 6 illustrates a top cross-sectional view of the exemplary metal enclosure for electrical components of FIG. 1.

FIG. 7 illustrates a magnified view of the top cross-sectional view of FIG. 6 of the exemplary metal enclosure for electrical components of FIG. 1.

FIG. 8 illustrates another magnified view of the top cross-sectional view of FIG. 6 of the exemplary metal enclosure for electrical components of FIG. 1.

FIG. 9 illustrates a side cross-sectional view of the exemplary metal enclosure for electrical components of FIG. 1.

FIG. 10 illustrates a magnified view of the side cross-sectional view of FIG. 9 of the exemplary metal enclosure for electrical components of FIG. 1.

FIG. 11 illustrates another magnified view of the side cross-sectional view of FIG. 9 of the exemplary metal enclosure for electrical components of FIG. 1.

FIG. 12 illustrates a rear cross-sectional view of the exemplary metal enclosure for electrical components of FIG. 1.

### DETAILED DESCRIPTION

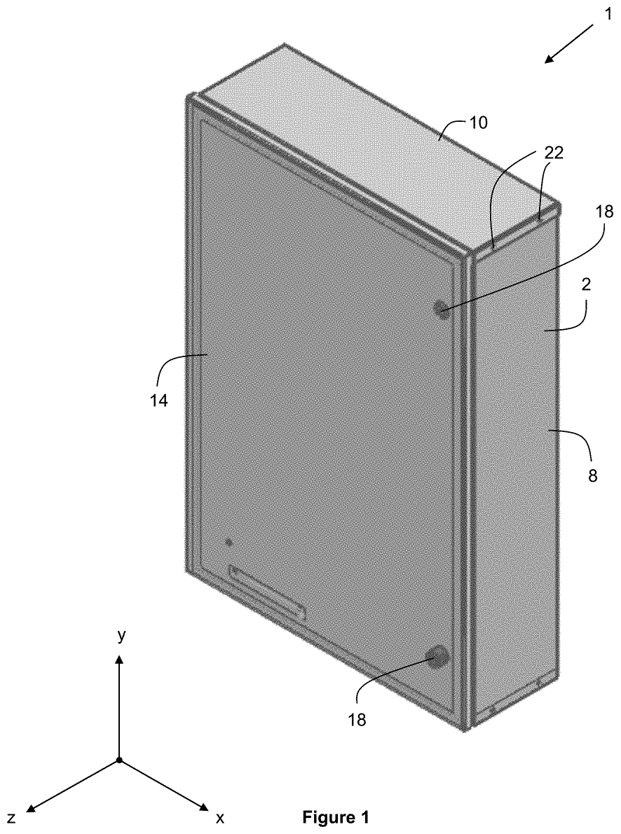

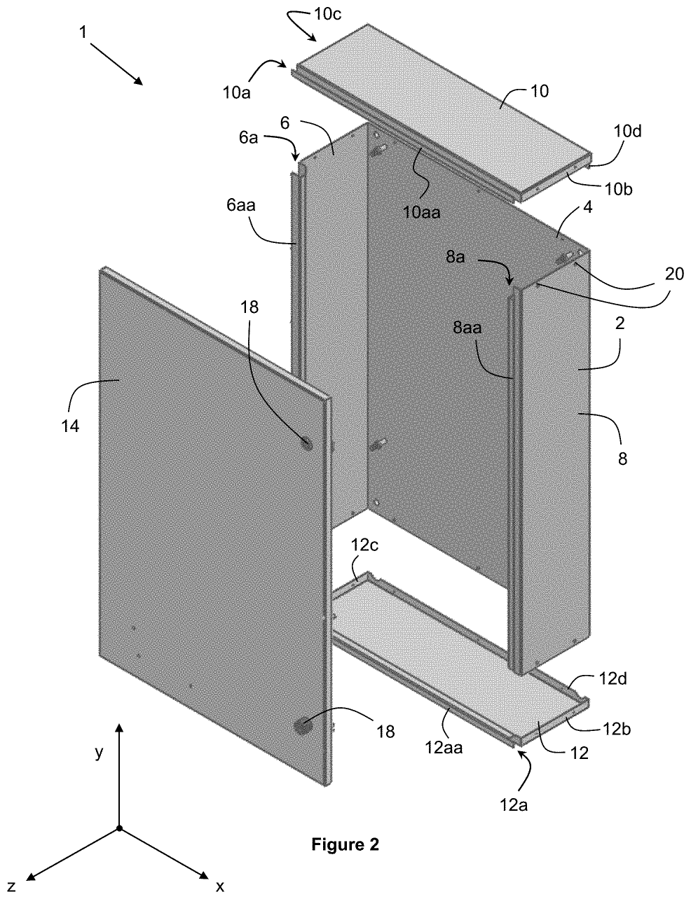

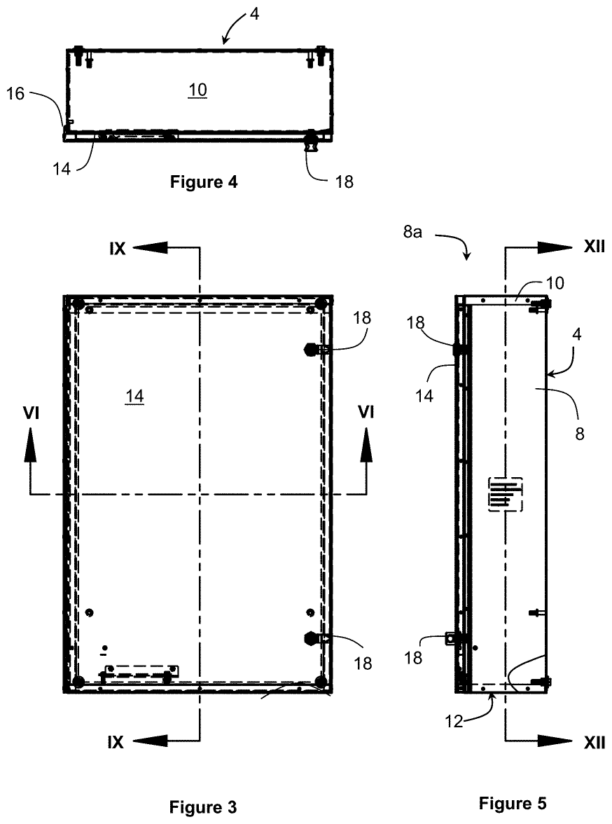

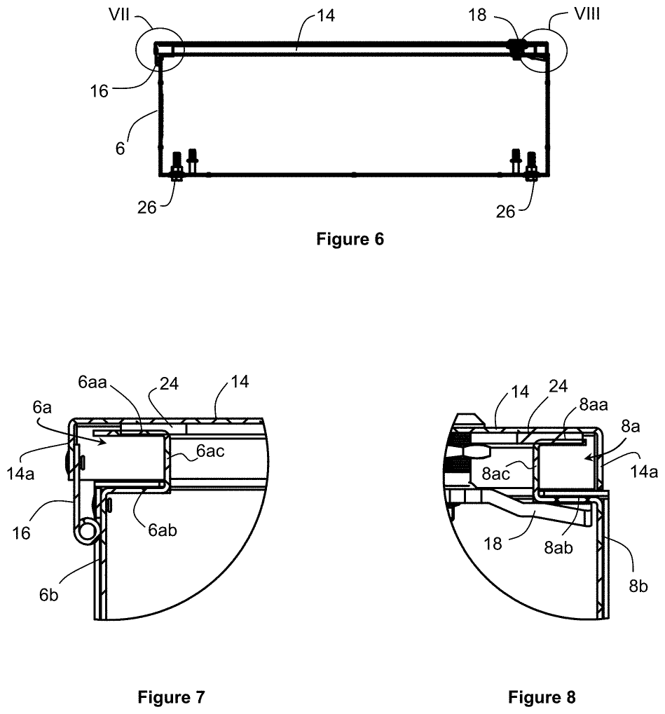

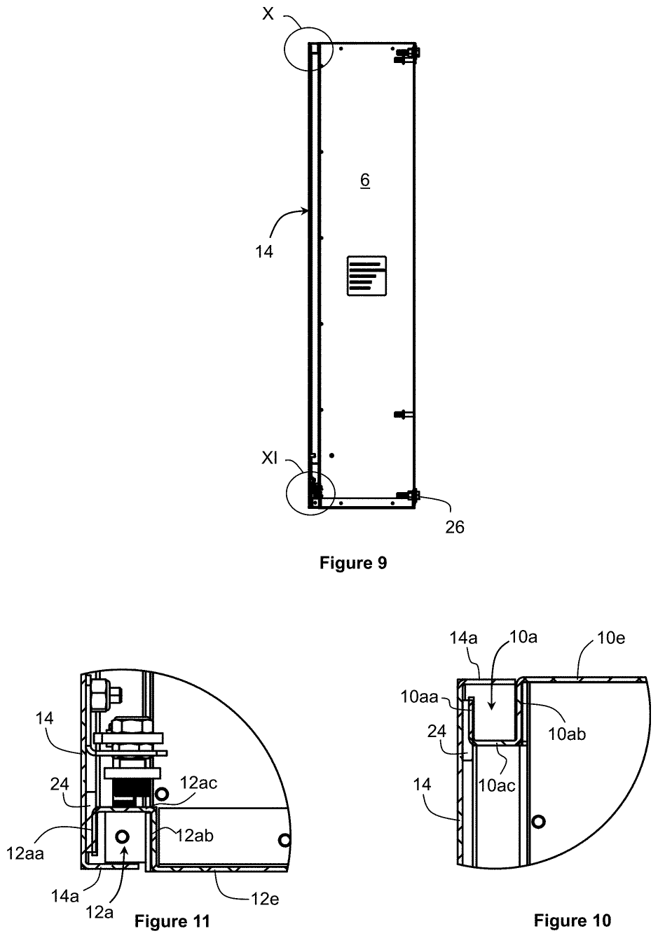

FIGS. 1-12 illustrate various views of an exemplary metal enclosure 1 for electrical components. The enclosure 1 may include a main body 2 including a rear panel 4, a right side panel 6, and a left side panel 8 that are bent substantially perpendicular to the rear panel 4. The enclosure 1 may also include a top panel 10 and a bottom panel 12. In the illustrated embodiment of FIG. 2, the main body 2 defines an enclosure volume with a front opening, a top opening, and a bottom opening. The top panel 10 may correspond to the top opening while the bottom panel 12 may correspond to the bottom opening. The enclosure 1 may also include a door 14 and a hinge 16 that connects the door 14 to the right side panel 6 or to the left side panel 8 such that the door 14 may be swung about the hinge 16 to open or close the enclosure 1. In one embodiment, the hinge 16 is a single (e.g., piano) hinge. In other embodiments, the door 14 connects to the right side panel 6 or to the left side panel 8 using a single hinge 16 or multiple hinges 16 of a potential variety of different types such that the door 14 may be swung about the hinger or hinges 16 to open or close the enclosure 1. The door 14 may have a one or more latches 18 mounted thereon to latch the door 14 in the closed position.

In the embodiment of FIG. 2, the rear panel 4 and the two side panels 6, 8 are formed by a single piece of sheet metal bent into the shown shape without welding. In other embodiments, the top panel 10 and the bottom panel 12 instead of or in addition to the two side panels 6, 8 may be formed together with the rear panel 4 by a single sheet of sheet metal without welding. Each of the right side panel 6, left side panel 8, top panel 10, and bottom panel 12 may have formed thereon a respective recessed channel 6a, 8a, 10a, 12a.

In the illustrated embodiment, the top panel 10 has formed thereon overlap flanges 10b, 10c, 10d. Similarly, the bottom panel 12 may have formed thereon overlap flanges 12b, 12c, 12d. In other embodiments, instead of or in addition to the top panel 10 and the bottom panel 12 having formed thereon flanges, the rear panel 4 and the two side panels 6, 8 may have formed thereon overlap flanges. When assembled, flanges 10b, 10c, 10d and flanges 12b, 12c, 12d may overlap corresponding portions of the rear panel 4 and the two side panels 6, 8, thereby providing surfaces for adhesive coupling of the main body 2 to the top panel 10 and the bottom panel 12. Similarly, in the case the rear panel 4 and the two side panels 6, 8 have flanges formed thereon, such flanges may overlap corresponding portions of the top panel 10 and the bottom panel 12, thereby providing surfaces for adhesive coupling of the main body 2 to the top panel 10 and the bottom panel 12.

The enclosure 1 may be assembled by bringing the rear panel 4, the right side panel 6, the left side panel 8, the top panel 10, and the bottom panel 12 together and applying adhesive at the overlapping surfaces. In one embodiment, the enclosure 1 (e.g., the panels 4, 6, 8, 10, 12) may include holes 20 in which rivets 22 may be inserted, not necessarily to structurally retain the enclosure 1 together permanently, but to retain the structure 1 together while the adhesive cures. In other embodiments, minimal spot or tack welding, or tooling or jigs, among other methods, may also be used to retain the structure 1 together while the adhesive cures, in addition to, or instead of the rivets 22. The panels 4, 6, 8, 10, 12 adhered together form a case having a cavity or volume with a front opening. The door 14 may be swung about the hinge 16 to open or close the front opening of the enclosure 1.

In one embodiment, each of the panels 4, 6, 8, 10, 12 is fabricated from galvanized or non-galvanized sheet metal and the panels 4, 6, 8, 10, 12 are adhered to each other using a suitable adhesive such as an acrylic or epoxy structural adhesive. The hinge 16 may be welded, bolted, glued, etc. to the door 14 and the right side panel 6 or the left side panel 8 to hingedly connect the door 14 to the rest of the enclosure 1. The assembled enclosure 1 may then be painted or powder coated to further protect the enclosure against corrosion.

Each of the right side panel 6, left side panel 8, top panel 10, and bottom panel 12 may have formed thereon the respective recessed channel 6a, 8a, 10a, 12a that, upon bonding together of the panels 4, 6, 8, 10, 12, meet to form a case channel circumscribing the front opening of the enclosure 1. As best seen in FIGS. 7,8, 10, and 11, each of the recessed channels 6a, 8a, 10a, 12a and, therefore, the case channel extend forward (i.e., towards the door 14 in the z direction) away from a volume encompassed by the enclosure 1 and are recessed towards a center of the front opening of the enclosure 1 (i.e., the recessed channels 6a and 8a extend inwardly in the x direction towards the center of the front opening and the recessed channels 10a and 12a extend inwardly in the y direction towards the center of the front opening). In one embodiment, each of the recessed channels 6a, 8a, 10a, 12a and, therefore, the case channel are recessed so as to not extend radially beyond an envelope formed by planes of main panes of the sides, top, and bottom metal panels 6, 8, 10, 12. The case channel routes any rainwater that reaches it away from the enclosure's opening and its interior volume.

As best seen in FIGS. 7, 8, 10, and 11, each of the recessed channels 6a, 8a, 10a, 12a has a front flange 6aa, 8aa, 10aa, 12aa. Moreover, in the illustrated embodiment, an inner surface 14a of the door 14 may have attached thereon a gasket 24 that, when the door 14 is closed, engages the front flanges 6aa, 8aa, 10aa, 12aa to seal the metal enclosure 1 when the door 14 is closed. In other embodiments, the gasket 24 may instead be attached to the front flanges 6aa, 8aa, 10aa, 12aa or other portion of the enclosure 1 to seal the metal enclosure 1 when the door 14 is closed. When the door 14 is closed and (as best seen in FIG. 8) the latches 18 latch against the recessed channel 8a, the gasket 24 seals against the front flanges 6aa, 8aa, 10aa, 12aa and the adhesive seals between the panels 4, 6, 8, 10, 12 to provide a weather and dust proof enclosure without the need for significant spot or line welding.

As best seen in FIG. 7, the right side recessed channel 6a may have a c-shaped cross section including a first flange 6ab at a substantially right angle relative to a main pane 6b of the right side panel 6, a second flange 6ac at a substantially right angle relative to the first flange 6ab, and the third flange 6aa at a substantially right angle relative to the second flange 6ac. The third flange 6aa may have a width of between 0.05 and 4 inches. In some embodiments, the third flange 6aa does not extend radially beyond an envelope formed by the plane of main pane 6b of the right side metal panel 6. In some embodiments, the right side recessed channel 6a may have an L-shaped cross section including the first flange 6ab at a substantially right angle relative to the main pane 6b of the right side panel 6 and the second flange 6ac at a substantially right angle relative to the first flange 6ab.

As best seen in FIG. 8, the left side recessed channel 8a may have a c-shaped cross section including a first flange 8ab at a substantially right angle relative to a main pane 8b of the left side panel 8, a second flange 8ac at a substantially right angle relative to the first flange 8ab, and the third flange 8aa at a substantially right angle relative to the second flange 8ac. The third flange 8aa may have a width of between 0.05 and 4 inches. In some embodiments, the third flange 8aa does not extend radially beyond an envelope formed by the plane of main panes 8b of the left side metal panel 8. In some embodiments, the left side recessed channel 8a may have an L-shaped cross section including the first flange 8ab at a substantially right angle relative to the main pane 8b of the left side panel 8 and the second flange 8ac at a substantially right angle relative to the first flange 8ab.

As best seen in FIG. 10, the top recessed channel 10a may have a c-shaped cross section including a first flange 10ab at a substantially right angle relative to a main pane 10e of the top panel 10, a second flange 10ac at a substantially right angle relative to the first flange 10ab, and the third flange 10aa at a substantially right angle relative to the second flange 10ac. The third flange 10aa may have a width of between 0.05 and 4 inches. In some embodiment, third flange 10aa does not extend radially beyond an envelope formed by the plane of main pane 10e of the top metal panel 10. In some embodiments, the top recessed channel 10a may have an L-shaped cross section including the first flange 10ab at a substantially right angle relative to the main pane 10e of the top panel 10 and the second flange 10ac at a substantially right angle relative to the first flange 10ab.

As best seen in FIG. 11, the bottom recessed channel 12a may have a c-shaped cross section including a first flange 12ab at a substantially right angle relative to a main pane 12b of the bottom panel 12, a second flange 12ac at a substantially right angle relative to the first flange 12ab, and the third flange 12aa at a substantially right angle relative to the second flange 12ac. The third flange 12aa may have a width of between 0.05 and 4 inches. In some embodiments, the third flange 12aa does not extend radially beyond an envelope formed by the plane of main pane 12e of the bottom metal panel 12. In some embodiments, the bottom recessed channel 12a may have an L-shaped cross section including the first flange 12ab at a substantially right angle relative to the main pane 12e of the bottom panel 12 and the second flange 12ac at a substantially right angle relative to the first flange 12ab.

As best seen in FIGS. 1 and 2, the door 14 may have at least one flange 14a formed on its perimeter. As best seen in FIGS. 7, 8, 10, and 11, the flange 14a extends towards the main body 2 when the door 14 is closed such that the flange 14a at least partially covers the right side recessed channel 6a, the left side recessed channel 8a, the top recessed channel 10a, and the bottom recessed channel 12a. This way, the flange 14a may further protect the inside of the enclosure 1 from weather and dust (and even from electromagnetic interference leaking through the adhesive at imperfections in the abutting recessed channels 6a, 8a, 10a, 12a) without the need for significant spot or line welding.

As best shown in FIG. 7, the hinge 16 may be operably connected (e.g., welded, bolted, glued, etc.) to the flange 14a of the door 14 and to the main pane 6b of the right side panel 6 or the main panes 8b of the left side panel 8 to hingedly connect the door 14 to the rest of the enclosure 1. As shown in the embodiment of FIG. 7, the hinge 16 may not be integral to the right side recessed channel 6a or the left side recessed channel 8a. Instead, the hinge 16 may be welded, bolted, glued, etc. to the door 14 and the right side panel 6 or the left side panel 8 to hingedly connect the door 14 to the rest of the enclosure 1.

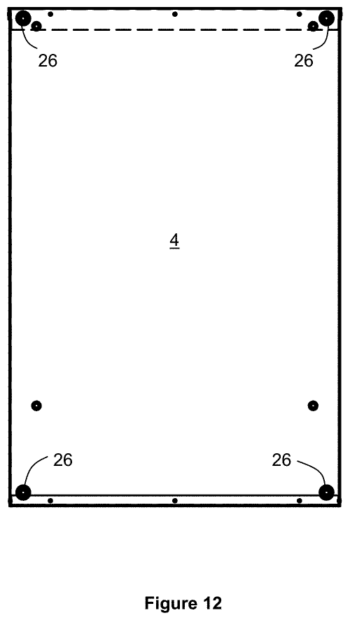

FIG. 12 illustrates an inside surface 4a of the rear panel 4. The rear panel 4 may have installed thereon mounting bolts 26 to mount the enclosure 1 to walls, posts, etc.

Upon curing of the adhesive, the enclosure 1 as disclosed herein is as structurally adequate as a welded enclosure and provides weather, dust, electric, and electromagnetic protection/shielding. However, given that adhesive bonding of components is significantly less expensive than welding, the enclosure 1 as disclosed herein may be fabricated at a significantly lesser cost than prior art welded enclosures.

### Definitions

The following includes definitions of selected terms employed herein. The definitions include various examples or forms of components that fall within the scope of a term and that may be used for implementation. The examples are not intended to be limiting. Both singular and plural forms of terms may be within the definitions.

As used herein, an “operable connection” or “operable coupling,” or a connection by which entities are “operably connected” or “operably coupled” is one in which the entities are connected in such a way that the entities may perform as intended. An operable connection may be a direct connection or an indirect connection in which an intermediate entity or entities cooperate or otherwise are part of the connection or are in between the operably connected entities. In the context of signals, an “operable connection,” or a connection by which entities are “operably connected,” is one in which signals, physical communications, or logical communications may be sent or received. Typically, an operable connection includes a physical interface, an electrical interface, or a data interface, but it is to be noted that an operable connection may include differing combinations of these or other types of connections sufficient to allow operable control. For example, two entities can be operably connected by being able to communicate signals to each other directly or through one or more intermediate entities like a processor, operating system, a logic, software, or other entity. Logical or physical communication channels can be used to create an operable connection.

To the extent that the term “includes” or “including” is employed in the detailed description or the claims, it is intended to be inclusive in a manner similar to the term “comprising” as that term is interpreted when employed as a transitional word in a claim. Furthermore, to the extent that the term “or” is employed in the detailed description or claims (e.g., A or B) it is intended to mean “A or B or both”. When the applicants intend to indicate “only A or B but not both” then the term “only A or B but not both” will be employed. Thus, use of the term “or” herein is the inclusive, and not the exclusive use. See, Bryan A. Garner, A Dictionary of Modern Legal Usage 624 (2d. Ed. 1995).

While example systems, methods, and so on, have been illustrated by describing examples, and while the examples have been described in considerable detail, it is not the intention of the applicants to restrict or in any way limit scope to such detail. It is, of course, not possible to describe every conceivable combination of components or methodologies for purposes of describing the systems, methods, and so on, described herein. Additional advantages and modifications will readily appear to those skilled in the art. Therefore, the invention is not limited to the specific details, the representative apparatus, and illustrative examples shown and described. Thus, this application is intended to embrace alterations, modifications, and variations that fall within the scope of the appended claims. Furthermore, the preceding description is not meant to limit the scope of the invention. Rather, the scope of the invention is to be determined by the appended claims and their equivalents.

What is claimed is:

1. A metal enclosure for electrical components, the enclosure comprising:
a main body including a rear panel and two side panels all of which are formed at least in part by a single material sheet without welding, the main body defining an enclosure volume with a front opening, a top opening, and a bottom opening, a right side panel of the two side panels having formed thereon a right side recessed channel, and a left side panel of the two side panels having formed thereon a left side recessed channel, the right side recessed channel and the left side recessed channel extending forward away from the enclosure volume and recessed towards a center of the front opening;
a top panel adhesively and sealingly coupled to the main body at the top opening, the top panel having formed thereon a top rear flange, a top right flange, a top left flange, and a top recessed channel that extends forward away from the enclosure volume, is recessed towards the center of the front opening, and abuts the right side recessed channel and the left side recessed channel, the top rear flange, the top right flange, and the top left flange overlapping corresponding portions of the rear panel, the right side panel, and the left side panel, respectively, providing surfaces for adhesive coupling of the main body and the top panel;
a bottom panel adhesively and sealingly coupled to the main body at the bottom opening, the bottom panel having formed thereon a bottom recessed channel that extends forward away from the enclosure volume, is recessed towards the center of the front opening, and abuts the right side recessed channel and the left side recessed channel;
a door hingedly connected to the right side panel or the left side panel and having one or more latches mounted thereon; and
a gasket that, when the door is closed, engages an inner surface of the door and the right side recessed channel, the left side recessed channel, the top recessed channel, and the bottom recessed channel to seal the metal enclosure, the one or more latches configured to selectively latch the door closed.

2. The metal enclosure of claim 1, wherein the right side recessed channel has a c-shaped cross section including a first flange at a substantially right angle relative to a main pane of the right side panel, a second flange at a substantially right angle relative to the first flange, and a third flange at a substantially right angle relative to the second flange, a front surface of the right side recessed channel corresponds to a front surface of the third flange, the third flange having a width of between 0.05 and 4.0 inches, wherein the left side recessed channel has a c-shaped cross section including a first flange at a substantially right angle relative to a main pane of the left side panel, a second flange at a substantially right angle relative to the first flange, and a third flange at a substantially right angle relative to the second flange, a front surface of the left side recessed channel corresponds to a front surface of the third flange, the third flange having a width of between 0.05 and 4.0 inches.

3. The metal enclosure of claim 1, wherein the top recessed channel has a c-shaped cross section including a first flange at a substantially right angle relative to a main pane of the top panel, a second flange at a substantially right angle relative to the first flange, and a third flange at a substantially right angle relative to the second flange, a front surface of the top recessed channel corresponds to a front surface of the third flange, the third flange having a width of between 0.05 and 4.0 inches, wherein the bottom recessed channel has a c-shaped cross section including a first flange at a substantially right angle relative to a main pane of the bottom panel, a second flange at a substantially right angle relative to the first flange, and a third flange at a substantially right angle relative to the second flange, a front surface of the bottom recessed channel corresponds to a front surface of the third flange, the third flange having a width of between 0.05 and 4.0 inches.

4. The metal enclosure of claim 1, wherein
the right side recessed channel has a c-shaped cross section including a first flange at a substantially right angle relative to a main pane of the right side panel, a second flange at a substantially right angle relative to the first flange, and a third flange at a substantially right angle relative to the second flange, a front surface of the right side recessed channel corresponds to a front surface of the third flange,
the left side recessed channel has a c-shaped cross section including a first flange at a substantially right angle relative to a main pane of the left side panel, a second flange at a substantially right angle relative to the first flange, and a third flange at a substantially right angle relative to the second flange, a front surface of the left side recessed channel corresponds to a front surface of the third flange,
the top recessed channel has a c-shaped cross section including a first flange at a substantially right angle relative to a main pane of the top panel, a second flange at a substantially right angle relative to the first flange, and a third flange at a substantially right angle relative to the second flange, a front surface of the top recessed channel corresponds to a front surface of the third flange, and
the bottom recessed channel has a c-shaped cross section including a first flange at a substantially right angle relative to a main pane of the bottom panel, a second flange at a substantially right angle relative to the first flange, and a third flange at a substantially right angle relative to the second flange, a front surface of the bottom recessed channel corresponds to a front surface of the third flange.

5. The metal enclosure of claim 1, wherein
the right side recessed channel has a cross section including a first flange at a substantially right angle relative to a main pane of the right side panel and a second flange at a substantially right angle relative to the first flange,
the left side recessed channel has cross section including a first flange at a substantially right angle relative to a main pane of the left side panel and a second flange at a substantially right angle relative to the first flange,
the top recessed channel has a cross section including a first flange at a substantially right angle relative to a main pane of the top panel and a second flange at a substantially right angle relative to the first flange, and
the bottom recessed channel has a cross section including a first flange at a substantially right angle relative to a main pane of the bottom panel and a second flange at a substantially right angle relative to the first flange.

6. The metal enclosure of claim 1, the bottom panel having formed thereon a bottom rear flange, a bottom right flange, and a bottom left flange, the top rear flange, the top right flange, and the top left flange overlapping corresponding portions of the rear panel, the right side panel, and the left side panel, respectively, providing surfaces for adhesive coupling of the main body to the bottom panel.

7. The metal enclosure of claim 1, wherein the door has at least one flange formed on its perimeter, the at least one flange extending towards the main body when the door is closed such that the at least one flange at least partially covers the right side recessed channel, the left side recessed channel, the top recessed channel, and the bottom recessed channel.

8. The metal enclosure of claim 7, comprising:
a hinge operably connected to the at least one flange of the door and to the main pane of the right side panel or the main pane of the left side panel to hingedly connect the door and the right side panel or the left side panel.

9. The metal enclosure of claim 7, comprising:
a hinge that is not integral to the right side recessed channel or the left side recessed channel, the hinge operably connected to the door and bolted or glued to the right side panel or the left side panel to hingedly connect the door and the right side panel or the left side panel.

10. A metal enclosure for electrical components, the enclosure comprising:
a main body including a rear panel and two adjoined panels bent perpendicular to the rear panel all of which are formed at least in part by a single material sheet without welding, the main body defining an enclosure volume with a front opening and two openings perpendicular to the front opening, each of the two adjoined panels having formed thereon a respective recessed channel that extends forward away from the enclosure volume and is recessed towards a center of the front opening,
two separate panels including first and second separate panels adhesively and sealingly coupled to the main body at first and second of the two openings, respectively, each of the two separate panels having formed thereon a respective recessed channel that extends forward away from the enclosure volume and is recessed towards a center of the front opening;
a door hingedly connected to one of the two adjoined panels or one of the two separate panels and having one or more latches mounted thereon; and
a gasket that, when the door is closed, engages a main panel of the door and the recessed channels of the two adjoined panels and of the two separate panels to seal the metal enclosure, the one or more latches configured to selectively latch the door closed,
the rear panel and the two adjoined panels having formed thereon flanges at the interface of the rear panel and the two separate panels and at the interface of the two adjoined panels and the two separate panels, respectively, or the two separate panels having formed thereon flanges at the interface of the rear panel and the two separate panels and at the interface of the two adjoined panels and the two separate panels, respectively.

11. The metal enclosure of claim 10, wherein each of the recessed channels has a c-shaped cross section including a first flange at a substantially right angle relative to a main pane of the respective panel, a second flange at a substantially right angle relative to the first flange, and a third flange at a substantially right angle relative to the second flange, front surfaces of the recessed channels corresponding to a front surface of the third flange.

12. The metal enclosure of claim 11, the door having a perimeter having formed thereon at least one flange extending away from the main panel such that, when the door is closed, the at least one flange at least partially covers each of the recessed channels.

13. The metal enclosure of claim 12, comprising:
a hinge operably connected to the door and to the main pane of the one of the two adjoined panels or the one of the two separate panels to hingedly connect the door.

14. The metal enclosure of claim 12, comprising:
a hinge operably connected to the door and bolted or glued to the one of the two adjoined panels or the one of the two separate panels to hingedly connect the door.

15. A metal enclosure for electrical components, the enclosure comprising:
a rear metal panel and four side metal panels with overlapping portions coupled with adhesive to form a bonded case having a cavity with a front opening, channels of the four side metal panels joined to form a case channel circumscribing the opening, the case channel recessed towards a center of the opening so as to not extend radially beyond an envelope formed by planes of main panes of the four side metal panels of the one of the two adjoined panels or the one of the two separate panels; and
a door hingedly connected to one of the four side metal panels and having one or more latches installed thereon; and
a gasket that, when the door is closed, engages a main panel of the door and the case channel to seal the metal enclosure, the one or more latches configured to selectively latch the door closed.

16. The metal enclosure of claim 15, wherein each of the channels has a c-shaped cross section including a first flange bent away from a main pane of the respective side metal panel, a second flange bent away from the first flange, and a third flange bent away from the second flange, the front surface of the case channel corresponding to front surfaces of the third flanges.

17. The metal enclosure of claim 16, the door having at least one perimeter flange extending perpendicular to the main panel such that, when the door is closed, the at least one perimeter flange at least partially covers the case channel.

18. The metal enclosure of claim 17, comprising:
a hinge operably connected to the door and to one of the main panes of the four side metal panels to hingedly connect the door to the bonded case.

19. The metal enclosure of claim 17, comprising:
a hinge operably connected to the door and bolted or glued to one of the four side metal panels to hingedly connect the door to the bonded case.

20. The metal enclosure of claim 15, wherein a rear metal panel and four side metal panels have corresponding holes formed thereon in which rivets are inserted to support the case while the adhesive cures.
